(19) United States
(12) Patent Application Publication
(10) Pub. No.: US 2007/0145578 A1
(43) Pub. Date: Jun. 28, 2007

(54) Multi-chip package sharing temperature-compensated self-refresh signal and method thereof

(75) Inventor: Heon-Gwon Lee, Anyang-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/606,282

(22) Filed: Nov. 30, 2006

(30) Foreign Application Priority Data
Dec. 23, 2005 (KR) 10-2005-0128674

(51) Int. Cl. H01L 23/34

(52) U.S. Cl. 257/723

(57) ABSTRACT

A multi-chip package sharing a temperature-compensated self-refresh (TCSR) signal and method thereof is disclosed. The multi-chip package may include a plurality of chips. At least one of the plurality of chips may generate a TCSR signal. A remainder of the plurality of chips may be configured to receive the TCSR signal. A pad may be commonly connected to the plurality of chips.

### PRIORITY STATEMENT

This application claims priority under 35 USC § 119 to Korean Patent Application No. 2005-128674, filed on Dec. 23, 2005, in the Korean Intellectual Property Office (KIPO), the entire contents of which are incorporated herein by reference.

### BACKGROUND

1. Field

Example embodiments relate to semiconductor packages, for example, semiconductor packages which adopt a temperature-compensated self-refresh (TCSR) scheme and methods for performing the same.

2. Description of the Related Art

To meet the recently growing demand for mobile devices, various package technologies have been developed, for example, vertically stacking a plurality of chips onto a common area, or stacking a logic unit and memory unit together.

These package technologies may not, however, include a scheme for temperature compensation, for example, temperature-compensated self-refresh (TCSR), as sometimes applied to conventional dynamic random-access memory (DRAM) systems. Because leakage currents in semiconductor elements, for example, cell capacitors, may be temperature dependent, compensation may help limit unnecessary current consumption. For example, a TCSR scheme may control the refresh period of the system such that when the detected temperature is low, current consumption may be reduced by maintaining a longer refresh period without sacrificing data integrity.

Recent semiconductor memory devices may execute a TCSR by detecting an internal temperature using a temperature sensor included in the memory device and adjusting the refresh period accordingly. This may be beneficial where power consumption is a concern, for example, in mobile devices. Because the self-refresh current will flow as long as the memory device is powered on, even if all other internal devices are turned off, reducing the self-refresh current when the environment permits may have an effect on overall power consumption.

In the conventional art relating to TCSR implementation in DRAM, semiconductor memory devices may include elements whose internal characteristics vary according to temperature, for example, the above-mentioned cell capacitors. These internal characteristics are compensated for within different temperature intervals by an output signal of the temperature sensor feeding into a controlling circuit used to adjust the refresh period.

Heretofore, in applying the conventional TCSR scheme to a multi-chip package, each chip has included its own TCSR circuitry. Each chip thus contains redundant circuitry for controlling the refresh period, which generates additional current consumption.

### SUMMARY

Example embodiments are directed to a semiconductor memory package that may share a temperature-compensated self-refresh (TCSR) signal among a plurality of chips in the package. Example embodiments are directed to a method for sharing a TCSR signal among a plurality of chips in a semiconductor memory package. Example embodiments are directed to a multi-package arrangement that may share a temperature-compensated self-refresh (TCSR) signal among a plurality of chips in the arrangement.

According to example embodiments, a multi-chip package may include a plurality of chips, where at least one of the plurality of chips may generate a TCSR signal. A remainder of the plurality of chips may be configured to receive the TCSR signal. The plurality of chips may be commonly connected through a pad.

In example embodiments, a multi-chip package may include a first chip, a second chip, and a pad. The first chip may generate a TCSR signal. The second chip may be configured to receive the TCSR signal. The pad may be commonly connected to both chips.

According to example embodiments, the pad may be formed in a substrate. The first chip may include an output pin, which may have variable operating states according to enable/disable signals. The enable/disable signals may be applied from an option circuit. The option circuit may use a fuse option circuit. The multi-chip package may include an input pin receiving the TCSR signal from the pad when the second chip does not provide a TCSR function.

In some example embodiments, a multi-chip package may include a plurality of chips, where at least one of the plurality of chips may generate a TCSR signal. A remainder of the plurality of chips may be configured to receive a TCSR signal. The plurality of chips may be commonly connected to a pad, where the pad may receive the TCSR signal and the remainder of the plurality of chips may receive the TCSR signal via the pad.

In some example embodiments, the pad may be formed in a substrate. The at least one of the plurality of chips may include an output pin, which may have variable operating states according to enable/disable signals. The enable/disable signals may be applied from an option circuit. The option circuit may use a fuse option circuit. The multi-chip package may include an input pin receiving the TCSR signal from the pad when the second chip does not provide a TCSR function.

In example embodiments, a multi-chip package may include a plurality of chips, where each of the plurality of chips may generate a corresponding TCSR signal. A remainder of the plurality of chips may be configured to receive the TCSR signal. The plurality of chips may be commonly connected through a pad.

In example embodiments, the pad may be formed in a substrate. The pad may be arranged in an unoccupied space of the package. Each of the plurality of chips may include an output pin, where the output pin may have variable operating states according to enable/disable signals. The enable/disable signals may be applied from an option circuit. The option circuit may use a fuse option circuit. The multi-chip package may include an input pin receiving the TCSR signal from the pad when the second chip does not provide a TCSR function.

According to example embodiments, multiple packages of chips may be arranged to share a TCSR signal. The arrangement may include at least one package providing TCSR functionality in addition to any number of multi-chip packages that may or may not provide TCSR functionality.

In example embodiments, a method for sharing a TCSR signal among a plurality of chips in a multi-chip package may include generating a TCSR signal at at least one of the plurality of chips. The TCSR signal may be transmitted to a pad commonly connected to the plurality of chips. A remainder of the plurality of chips may be permitted access to the TCSR signal.

According to example embodiments, a multi-chip package may include two or more chips as set forth above in any combination. According to example embodiments, a multi-chip package may include another multi-chip package, including a plurality of chips, at least one of the plurality of chips generating another temperature-compensated self-refresh (TCSR) signal, a remainder of the plurality of chips configured to receive the TCSR signal, and a pad commonly connected to the plurality of chips, wherein each of the plurality of chips generates a corresponding TCSR signal. According to example embodiments, a multi-chip package may include two or more chips as further set forth above in any combination.

### BRIEF DESCRIPTION OF THE DRAWINGS

The above and other features and advantages of example embodiments will become more apparent by describing in detail example embodiments thereof with reference to the attached drawings in which:

FIG. 1 is a block diagram illustrating a multi-chip package including a temperature-compensated self-refresh (TCSR) generating circuit according to an example embodiment.

FIG. 2 is a top plan view illustrating a package adopting a TCSR function according to an example embodiment.

FIG. 3 is a cross-sectional view illustrating a package according to an example embodiment.

FIG. 4 is a circuit diagram illustrating a control circuit for controlling a TCSR signal in the package in FIG. 3.

FIG. 5 is a cross-sectional view illustrating a package according to another example embodiment.

FIG. 6 is a circuit diagram illustrating a control circuit for controlling a TCSR signal in the package in FIG. 5.

FIG. 7 is a block diagram illustrating a cross-sectional view showing a mounted state of a package for sharing a TCSR signal between packages.

### DESCRIPTION OF THE EMBODIMENTS

Embodiments will be described more fully with reference to the accompanying drawings in which embodiments are shown. Embodiments many take different forms and should not be construed as limited to the embodiments set forth herein. Rather, these embodiments are provided so that this disclosure will be thorough and complete, and will fully convey the scope to those skilled in the art. Like reference numerals refer to like elements throughout this application.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the original scope. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this subject matter pertains. It will be further understood that terms, for example, those defined in commonly used dictionaries, should be interpreted as having a meaning that is consistent with their meaning in the context of the relevant art and will not be interpreted in an idealized or overly formal sense unless expressly so defined herein.

Example embodiments are directed to control appropriate parameters for sharing a temperature-compensated self-refresh (TCSR) function, as may be used in a dynamic random-access memory (DRAM) system, with other memory devices without modification according to temperature.

For this purpose, a chip may be packaged for sharing a TCSR signal, which drives a TCSR circuit, with an arbitrary chip.

FIG. 1 is a block diagram illustrating a multi-chip package 100 that may include a TCSR generating circuit 101, a device without a TCSR function 102, and/or a device with the TCSR function 103. A chip mounted on the package 100 may be a chip with the TCSR function or a chip without the TCSR function.

When one chip is capable of providing the TCSR function, the TCSR function may be shared with other chips, so that a temperature sensor may not have to be provided for every chip.

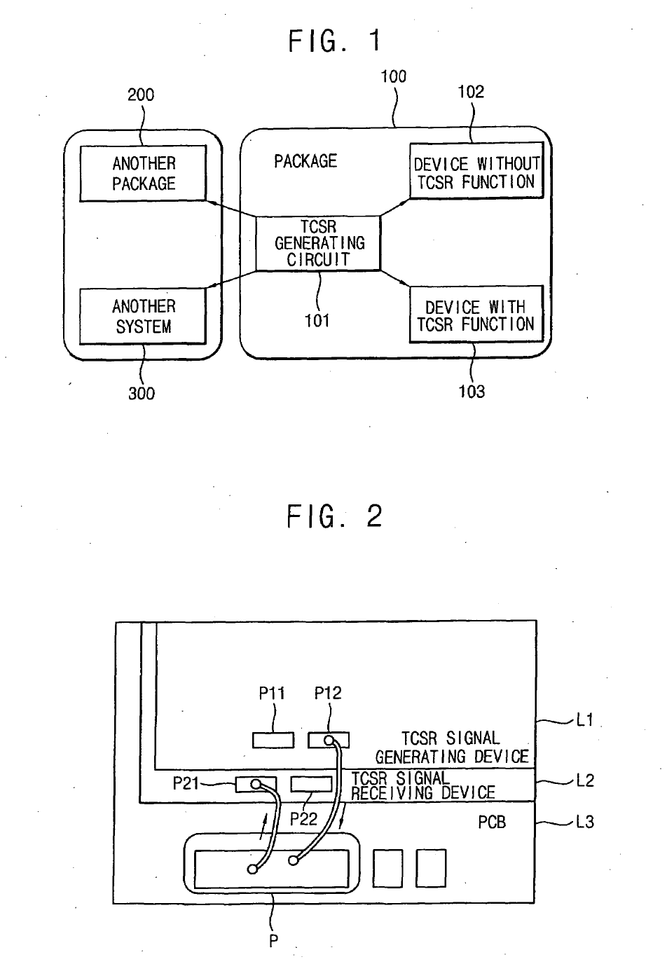

FIG. 2 is a top plan view illustrating a package including a TCSR function according to an example embodiment, wherein a chip disposed in a top layer L1 may provide a TCSR function, and a chip in a middle layer L2 may receive a TCSR signal. An extra space for a pad P is arranged to exchange TCSR signals among different layers. The extra space for the pad P may be arranged on a printed circuit board PCB of the bottom layer L3 or in an unoccupied space.

The chip disposed in the top layer L1 may include an input terminal P11 for inputting the TCSR signal and an output terminal P12. The chip disposed in the middle layer L2 may include an input terminal P21 for inputting the TCSR signal and an output terminal P22. Because the chip disposed in the top layer L1 may be a TCSR signal generating device, the output terminal P12 disposed in the top layer L1 may be electrically coupled to the pad P, and the input terminal P21 disposed in the middle layer L2 may be electrically coupled to the pad P for sharing the TCSR signal with other chips.

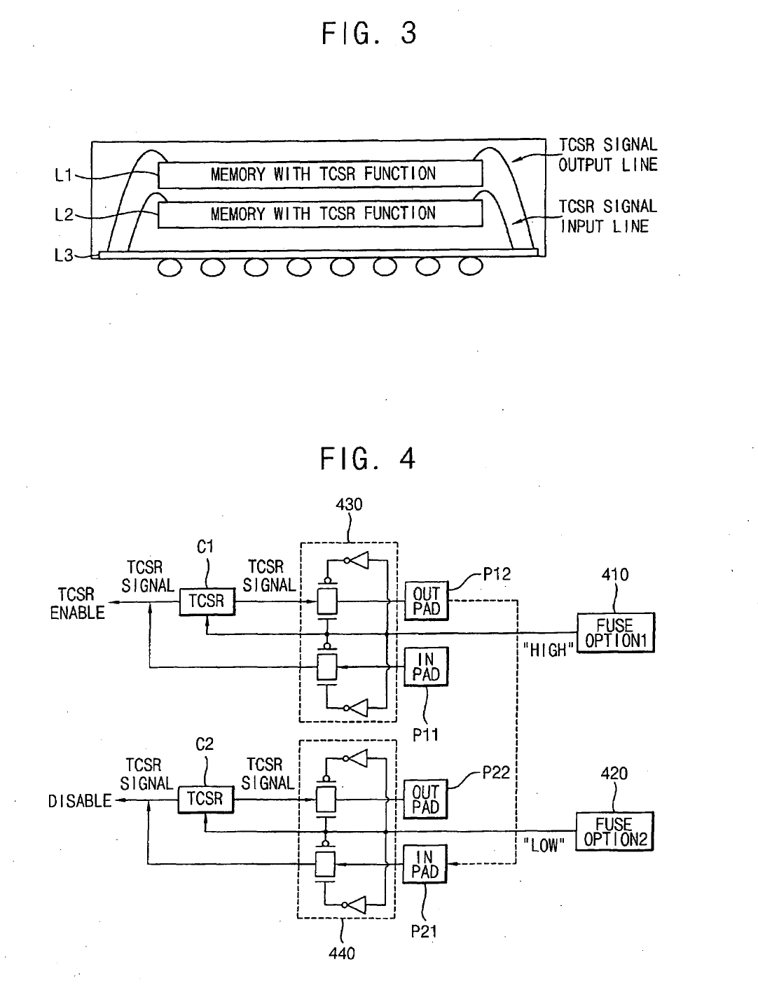

FIG. 3 is a cross-sectional view illustrating a package according to an example embodiment with two chips which are capable of providing a TCSR function within the package. When all of the chips disposed in the package may provide the TCSR function, only one TCSR function of the chips need be operated to provide the TCSR function to other chips.

The chip providing the TCSR function may provide the TCSR signal to the pad P via a TCSR signal output line electrically coupled to the output terminal P12 shown in FIG. 2. The chip not providing the TCSR function but receiving the TCSR signal from other chips receives the TCSR signal at the input terminal P21 via a TCSR signal input line electrically coupled to the pad P.

FIG. 4 illustrates a control circuit diagram for controlling a TCSR signal as in the package in FIG. 3. The TCSR signal may be enabled or disabled using a fuse option. The control circuit may include a first TCSR circuit C1, a second TCSR circuit C2, a first fuse option circuit 410, and/or a second fuse option circuit 420. The control circuit may also include a first gate unit 430 and a second gate unit 440.

The first TCSR circuit C1, which may receive a logic “high” from the first fuse option circuit 410, may be set to generate the TCSR signal, and the second TCSR circuit C2, which may receive a logic “low” from the second fuse option circuit 420, may be set to receive the TCSR signal.

When a chip for generating the TCSR signal is selected with the above setting, the first TCSR circuit C1 included in the chip may receive a logic “high” signal and the second TCSR circuit C2 may receive a logic “low” signal. The first TCSR circuit C1 may be in an enabled state and a detected temperature value may be applied to the output terminal P12 via the first gate unit 430. The detected temperature value applied to the output terminal P12 may be transferred to the input pad P21 of other chips coupled to the pad P. The temperature value applied to the input terminal P21 may be transferred to each device which receives the TCSR signal in the other chips via the second gate unit 440.

The second TCSR circuit C2, which may receive a logic “low” signal, may be in a disabled state and may receive the detected temperature value via the input terminal P21.

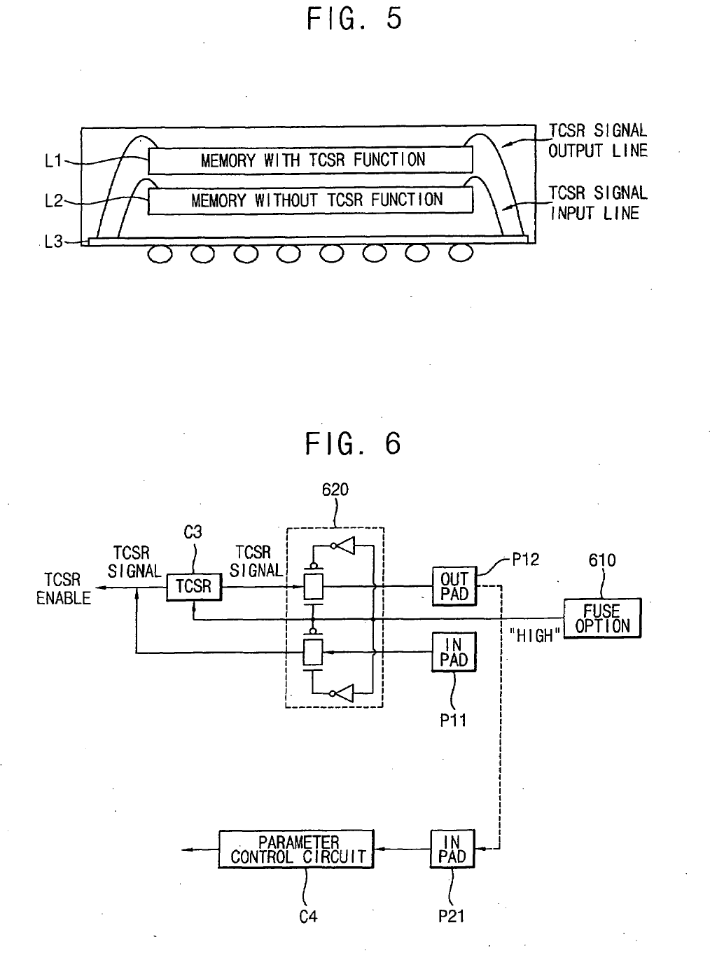

FIG. 5 is a cross-sectional view illustrating a package according to an example embodiment including a chip which is not capable of providing a TCSR function. A chip capable of providing a TCSR function may provide a TCSR signal to the pad P via a TCSR signal output line electrically coupled to the output terminal P12 shown in FIG. 2. A chip that is not capable of providing the TCSR function may receive the TCSR signal at the input terminal P21 via a TCSR input line electrically coupled to the pad P.

FIG. 6 is a circuit diagram illustrating a control circuit for controlling a TCSR signal in the package in FIG. 5. The control circuit may include a TCSR circuit C3, a parameter control circuit C4, a fuse option circuit 610 and/or a gate unit 620.

The TCSR circuit C3, which may receive a logic “high” signal from the fuse option circuit 610, may be set to generate the TCSR signal. The parameter control circuit C4 need not receive a signal from the fuse option circuit 610 because the chip including the parameter control circuit C4 does not have a device which provides the TCSR function. The chip including the parameter control circuit C4 may only have an input terminal P21 for receiving the TCSR signal.

When the TCSR circuit C3 receives a logic “high” signal, the TCSR circuit C3 may be in an enabled state and a detected temperature value may be applied to the output terminal P12 via the gate unit 620. The detected temperature value applied to the output terminal P12 may be transferred to the input terminal P21 of other chips. The detected temperature value may be transferred to the parameter control circuit C4 for handling the TCSR signal.

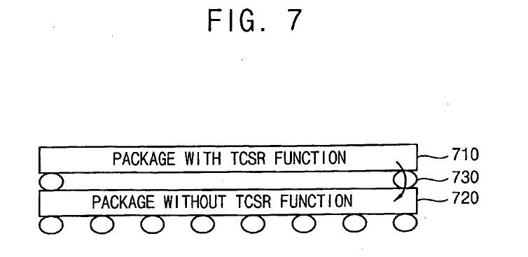

FIG. 7 is a block diagram of a cross-sectional view illustrating a multi-package arrangement for sharing a TCSR signal among several packages. The TCSR signal may be generated from a first package 710 which provides a TCSR function. The generated TCSR signal may then be transferred through a connector (for example, a ball 730) outside of the first package 710 to a second package 720 which does not provide the TCSR function.

It should be apparent to someone of ordinary skill in the art that this multi-package arrangement may be extended to any combination of at least one package generating a TCSR signal and any number of packages capable of receiving a TCSR signal, not merely example embodiments depicted in FIG. 7. A multi-package arrangement may, for example, include at least two multi-chip packages capable of generating and receiving TCSR signals. Furthermore, the TCSR signal generated in the first package 710 may also be shared with a logic circuit, a system-on-chip (SoC) or another system. The logic circuit, the SoC or other system may control a refresh period by sharing the TCSR signal including a detected temperature value.

As described above, the multi-chip package sharing a TCSR signal according to example embodiments may include a pad, input terminals and output terminals for exchanging signals, for example a TCSR signal. When one of the chips in the package provides a TCSR function, other chips may receive the shared TCSR signal.

Therefore, all of the chips in the multi-chip package sharing the TCSR signal according to example embodiments may share the TCSR function at lower cost. In addition, a refresh period of the entire memory package may be controlled by one TCSR device.

While example embodiments and their advantages have been described in detail, it should be understood that various changes, substitutions and alterations may be made herein without departing from the intended scope.

What is claimed is:

1. A multi-chip package, comprising:
a plurality of chips, at least one of the plurality of chips generating a temperature-compensated self-refresh (TCSR) signal, a remainder of the plurality of chips configured to receive the TCSR signal; and
a pad commonly connected to the plurality of chips.

2. The multi-chip package of claim 1, wherein the plurality of chips includes two chips, a first chip generating the TCSR signal and a second chip configured to receive the TCSR signal, the pad connected to the first chip and second chip.

3. The multi-chip package of claim 2, wherein the pad is formed in a substrate.

4. The multi-chip package of claim 2, wherein the first chip includes and output pin, the output pin having variable operating states according to enable/disable signals.

5. The multi-chip package of claim 4, wherein the enable/disable signals are applied from an option circuit.

6. The multi-chip package of claim 5, wherein the option circuit uses a fuse option circuit.

7. The multi-chip package of claim 2, wherein the multi-chip package includes an input pin receiving the TCSR signal from the pad when the second chip does not provide a TCSR function.

8. The multi-chip package of claim 1, wherein the pad receives the TCSR signal, and the remainder of the plurality of chips receives the TCSR signal via the pad.

9. The multi-chip package of claim 8, wherein the pad is formed in a substrate.

10. The multi-chip package of claim 8, wherein the at least one of the plurality of chips includes an output pin, the output pin having variable operating states according to enable/disable signals.

11. The multi-chip package of claim 10, wherein the enable/disable signals are applied from an option circuit.

12. The multi-chip package of claim 11, wherein the option circuit uses a fuse option circuit.

13. The multi-chip package of claim 8, wherein the multi-chip package includes an input pin receiving the TCSR signal from the pad when the second chip does not provide a TCSR function.

14. The multi-chip package of claim 1, wherein each of the plurality of chips generates a corresponding TCSR signal.

15. The multi-chip package of claim 14, wherein the pad is formed in a substrate.

16. The multi-chip package of claim 14, wherein the pad is arranged in an unoccupied space of the package.

17. The multi-chip package of claim 14, wherein each of the plurality of chips includes an output pin, each output pin having variable operating states according to enable/disable signals.

18. The multi-chip package of claim 17, wherein the enable/disable signals are applied from an option circuit.

19. The multi-chip package of claim 18, wherein the option circuit uses a fuse option circuit.

20. The multi-chip package of claim 14, wherein the multi-chip package includes an input pin receiving the TCSR signal from the pad when the second chip does not provide a TCSR function.

21. A multi-package arrangement, comprising:
at least two multi-chip packages according to claim 1.

22. A multi-package arrangement, comprising:
at least two multi-chip packages according to claim 14.

23. A multi-package arrangement, comprising:
at least one multi-chip package according to claim 1;
another multi-chip package, including a plurality of chips, at least one of the plurality of chips generating another temperature-compensated self-refresh (TCSR) signal, a remainder of the plurality of chips configured to receive the TCSR signal, and a pad commonly connected to the plurality of chips, wherein each of the plurality of chips generates a corresponding TCSR signal.

24. A multi-package arrangement, comprising:
at least one multi-chip package according to claim 1;
another multi-chip package, including a plurality of chips each of the plurality of chips configured to receive the TCSR signal, and a pad commonly connected to the plurality of chips.

25. A multi-package arrangement, comprising:
at least one multi-chip package according to claim 14;
another multi-chip package, including a plurality of chips each of the plurality of chips configured to receive at least one of the corresponding TCSR signals, and a pad commonly connected to the plurality of chips.

26. A method for sharing a TCSR signal among a plurality of chips in a multi-chip package, comprising:
generating a TCSR signal at least one of the plurality of chips;
transmitting the TCSR signal to a pad commonly connected to the plurality of chips; and
permitting access to the TCSR signal by any of a remainder of the plurality of chips.
